(19) United States
(12) Patent Application Publication
(10) Pub. No.: US 2026/0157218 A1
(43) Pub. Date: Jun. 4, 2026

(54) REWORK SYSTEM AND FLIP CHIP ASSEMBLY

(71) Applicant: Prilit Optronics, Inc., Tainan City (TW)

(72) Inventors: Biing-Seng Wu, Tainan City (TW); Hsing-Ying Lee, Tainan City (TW); Tzu-Hsin Huang, Tainan City (TW)

(21) Appl. No.: 18/968,667

(22) Filed: Dec. 4, 2024

(51) Int. Cl. H01L 23/00

(52) U.S. Cl. CPC H10W 72/90; H10W 72/20; H10W 72/07254; H10W 72/242; H10W 72/9415; H10W 72/9445; H10W 72/963; H10W 72/967; H10W 90/722

(57) ABSTRACT

A rework system includes a substrate, a plurality of primary substrate pads disposed on the substrate, and a plurality of repair substrate pads disposed on the substrate. The repair substrate pads are adjacent and correspond to at least a part of the primary substrate pads.

### BACKGROUND OF THE INVENTION

### 1. Field of the Invention

The present invention generally relates to a bonding process, and more particularly to a rework system and a flip chip assembly.

### 2. Description of Related Art

The chip-on-glass (COG) bonding process typically involves using anisotropic conductive film (ACF) tape to attach a chip (e.g., an integrated circuit (IC)) to a glass substrate. This method ensures a secure and reliable connection between the IC and the glass. In the event that the IC fails, a thermal head can be employed to heat the IC, facilitating its removal from the substrate. Once the IC is removed, any residual adhesive or glue left on the glass substrate must be carefully cleaned off. After ensuring the substrate is clean and free of any residue, the IC bonding process can be performed again, using fresh ACF tape to reattach a new or repaired IC to the glass substrate. This meticulous process ensures the integrity and functionality of the display are maintained.

However, when components (such as micro-light-emitting diodes or microLEDs) are very small and the density of components on the glass is very high, the opaque ACF tape is likely to cover the components (causing the light-emitting components to be unable to emit light smoothly), and it may damage neighboring components when removing residual adhesive while repairing the chip.

Another method for IC bonding involves using a laser to weld the IC to the metal connection points on the glass substrate. During this process, the IC pins and the metal on the glass form a eutectic mixture, which is a specific alloy composition that melts and solidifies at a single temperature. This eutectic mixture provides a strong and reliable bond between the IC and the substrate. However, if the IC fails and needs to be reworked, the high joint strength and melting temperature of the eutectic mixture pose a challenge. The IC cannot be removed simply by heating it with a thermal head. Instead, external force or another laser process is required to detach the IC. Unfortunately, this removal process often damages the metal connection points on the glass substrate, making it impossible to reattach a new or repaired IC to the metal points during rework.

In addition, the current process involves using a laser to penetrate the aluminum (Al) pad from the back side of the chip. The laser heats the area until the tin (Sn) in the gold-tin (Au—Sn) solder bump dissolves, creating a eutectic mixture. This eutectic mixture forms a strong bond between the chip and the substrate. However, the laser wavelength is only capable of penetrating the silicon layer of the chip. When the laser reaches the circuit layer, the aluminum in the circuit generates a high temperature and begins to dissolve. This dissolution of aluminum can lead to the failure of the chip, as the integrity of the circuit is compromised. This process highlights the delicate balance required in precision laser applications to avoid damaging the intricate components of the chip.

A need has thus arisen to propose a novel scheme to overcome drawbacks of the conventional rework processes, and to allow the laser to transfer energy to the solder bumps to produce bonding without affecting the circuit function.

### SUMMARY OF THE INVENTION

In view of the foregoing, it is an object of the embodiment of the present invention to provide a rework system capable of reworking even the metal connection points on the substrate are damaged and allowing the laser to transfer energy to the solder bumps to produce bonding without affecting the circuit function.

According to one embodiment, a rework system includes a substrate, primary substrate pads and repair substrate pads. The primary substrate pads and the repair substrate pads are disposed on the substrate. The repair substrate pads are adjacent and correspond to at least a part of the primary substrate pads.

According to another embodiment, a flip chip assembly includes a chip that is flipped, a reflow area in a front portion of the chip, at least one metal layer, chip pads, a substrate, substrate pads and solder bumps. The metal layer is disposed in the front portion of the chip and bypasses the reflow area. The chip pads are located in the front portion of the chip and electrically connected to a metal layer. The substrate pads are disposed on the substrate, and are electrically connected to the chip pads via the solder bumps. Laser heating passes through the chip and the reflow area to melt the solder bumps.

### BRIEF DESCRIPTION OF THE DRAWINGS

FIG. 1 schematically shows a top view of a rework system according to one embodiment of the present invention;

FIG. 2A and FIG. 2B schematically show side views of the rework system of FIG. 1;

FIG. 3A through FIG. 3C schematically show top views of a primary substrate pad and a repair substrate pad of FIG. 1 and conductive wires disposed on the substrate and connected thereto;

FIG. 4A through FIG. 4D schematically show side views of a primary substrate pad and a repair substrate pad of FIG. 1 and conductive wires disposed on the substrate and connected thereto;

FIG. 5 schematically shows a side view of a flip chip assembly according to another embodiment of the present invention; and

FIG. 6 schematically shows a side view of a flip chip assembly according to a further embodiment of the present invention.

### DETAILED DESCRIPTION OF THE INVENTION

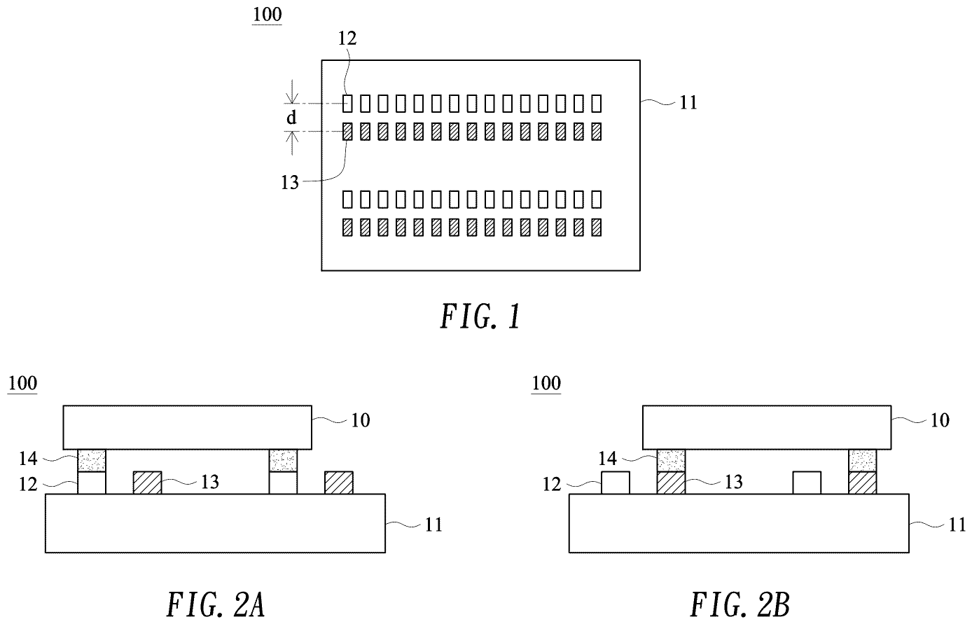

FIG. 1 schematically shows a top view of a rework system 100 according to one embodiment of the present invention. The rework system 100 of the embodiment may be adaptable to repairing a chip embedded with an integrated circuit (IC) such as a driver IC.

Specifically, the rework system 100 may include a substrate 11 (e.g., a glass substrate), on which a plurality of primary substrate pads 12, configured to establish electrical connections between the substrate 11 and a chip (not shown in FIG. 1), are disposed. The primary substrate pads 12 may include conductive material, for example, transparent conductive material such as indium tin oxide (ITO).

According to one aspect of the embodiment, the rework system 100 may include a plurality of repair (or dummy or redundant) substrate pads 13 disposed on the substrate 11. The repair substrate pads 13 may include conductive material, for example, transparent conductive material such as indium tin oxide (ITO). In the embodiment, the repair substrate pads 13 are adjacent and correspond to at least a part of the primary substrate pads 12 (with same pad spacing or pitch). As exemplified in FIG. 1, each row of repair substrate pads 13 is adjacent and parallel to a corresponding row of primary substrate pads 12. In the embodiment, a distance d between the repair substrate pads 13 and corresponding primary substrate pads 12 does not exceed a size (e.g., width or length) of the chip.

FIG. 2A schematically shows a side view of the rework system 100 of FIG. 1. As shown in FIG. 2A, a (flipped) chip 10 is interconnected to the primary substrate pads 12 via solder bumps 14 that are disposed on corresponding chip pads (not shown) of the chip 10. When rework is required, for example, when the chip 10 fails, desoldering is first performed to remove the chip 10 and the solder bumps 14 from the primary substrate pads 12, for example, by laser heating from the back or front of the chip. Next, re-soldering is performed to connect the solder bumps 14 of a new or repaired chip 10 to the repair substate pads 13 as shown in FIG. 2B, which schematically shows a side view of the rework system 100 of FIG. 1.

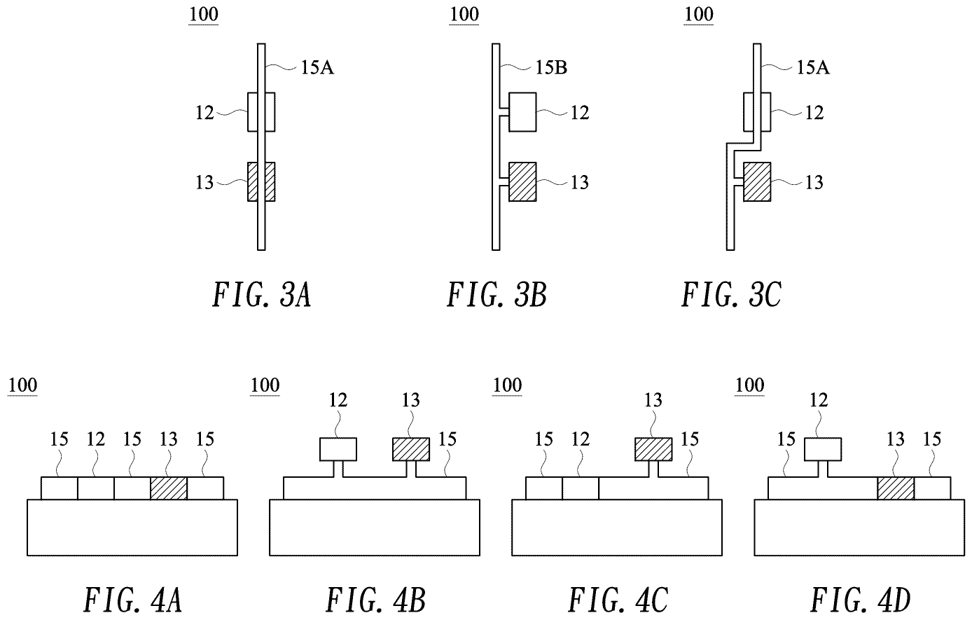

FIG. 3A through FIG. 3C schematically show top views of a primary substrate pad 12 and a repair substrate pad 13 of FIG. 1 and conductive wires 15A/B disposed on the substrate 11 and connected thereto. As exemplified in FIG. 3A, an original conductive wire 15A electrically connected to the primary substrate pad 12 is extended (in an original direction) and directly connected to the repair substrate pad 13. As exemplified in FIG. 3B, an extra conductive wire 15B is used to be indirectly connected to both the primary substrate pad 12 and the repair substrate pad 13. As exemplified in FIG. 3C, an original conductive wire 15A electrically connected to the primary substrate pad 12 is extended (with an original direction changed) and indirectly connected to the repair substrate pad 13.

FIG. 4A through FIG. 4D schematically show side views of a primary substrate pad 12 and a repair substrate pad 13 of FIG. 1 and conductive wires 15 disposed on the substrate 11 and connected thereto. As exemplified in FIG. 4A, the primary substrate pad 12, the repair substrate pad 13 and conductive wires 15 connected thereto are disposed on a same layer above the substrate 11. As exemplified in FIG. 4B, the primary substrate pad 12 and the repair substrate pad 13 are disposed above conductive wires 15. As exemplified in FIG. 4C, the repair substrate pad 13 is disposed above the primary substrate pad 12 and conductive wires 15. As exemplified in FIG. 4D, the primary substrate pad 12 is disposed above the repair substrate pad 13 and conductive wires 15.

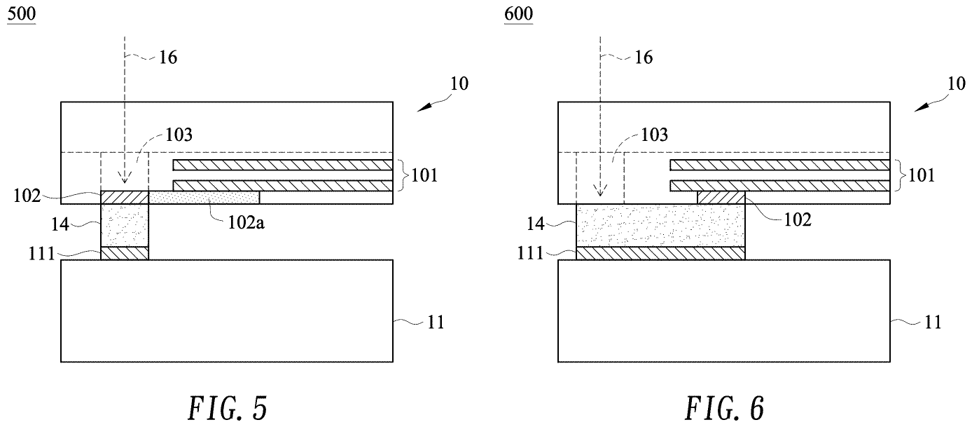

FIG. 5 schematically shows a side view of a flip chip assembly 500 according to another embodiment of the present invention. In the embodiment, the flip chip assembly 500 may include a (flipped) chip 10 embedded with an integrated circuit (IC) such as a driver IC. The chip 10 may include at least one metal layer 101 (two metal layers are exemplified in FIG. 5) configured to provide circuit function and disposed in a front portion of the chip 10. The chip 10 may include a plurality of chip pads 102 (located in the front portion of the chip 10 and) electrically connected to a metal layer 101 indirectly via an extension portion 102a. The flip chip assembly 500 may include a substrate 11 (e.g., a glass substrate) and a plurality of substrate pads 111 disposed on the substrate 11 and configured to establish electrical connections between the substrate 11 and (the chip pads 102 of) the chip 10 via corresponding solder bumps 14. In one embodiment, the solder bump 14 may include gold-tin (Au—Sn) alloy. When the flip chip assembly 500 is subjected to laser heating 16 (projected from the back of the chip 10 and) aligned with the chip pad 102, the solder bump 14 and the substrate pad 111, then the solder bump 14, the chip pad 102 and the substrate pad 111 result in an eutectic mixture, which is a type of a homogeneous mixture that has a melting point lower than those of the constituents.

According to one aspect of the embodiment, the metal layer 101 of the chip 10 bypasses a reflow area 103 in the front portion of the chip 10 accommodating the chip pad 102 and the reflow area 103 is vertically aligned with the laser heating 16 and the chip pad 102. Accordingly, the metal layer 101 will not be harmed when the flip chip assembly 500 is subjected to a reflow process by the laser heating 16 that passes through the chip 10 and the reflow area 103 to melt the solder bump 14 to form a conductive bond between substrate 11 and the chip 10.

FIG. 6 schematically shows a side view of a flip chip assembly 600 according to a further embodiment of the present invention. The flip chip assembly 600 of FIG. 6 is similar to the flip chip assembly 500 of FIG. 5 with the following exceptions.

According to one aspect of the embodiment, a reflow area 103 in the front portion of the chip 10 vertically aligned with the laser heating 16 is outside (e.g., in a periphery area of) an area corresponding to the metal layer 101 and does not accommodate the chip pad 102 (which is located in the aera corresponding to the metal layer 101 and is electrically connected to a metal layer 101 directly) . Further, the solder bump 14 is elongated in shape to connect (or be exposed) to a surface (such as the lower surface as exemplified in FIG. 6) of the reflow area 103 at one end and connect to the chip pad 102 at an opposite end. Accordingly, the metal layer 101 will not be harmed when the flip chip assembly 600 is subjected to a reflow process by the laser heating 16 that passes through the chip 10 and the reflow area 103 (from the back of the chip 10) to melt the solder bump 14 to form a conductive bond between substrate 11 and the chip 10.

Although specific embodiments have been illustrated and described, it will be appreciated by those skilled in the art that various modifications may be made without departing from the scope of the present invention, which is intended to be limited solely by the appended claims.

What is claimed is:

1. A rework system, comprising:
a substrate;
a plurality of primary substrate pads disposed on the substrate; and
a plurality of repair substrate pads disposed on the substrate;
wherein the plurality of repair substrate pads are adjacent and correspond to at least a part of the plurality of primary substrate pads.

2. The system of claim 1, wherein a distance between the plurality of repair substrate pads and corresponding primary substrate pads does not exceed a size of a chip to be repaired.

3. The system of claim 1, wherein the substrate comprises a glass substrate.

4. The system of claim 1, further comprising:
a plurality of solder bumps disposed on corresponding chip pads of a chip to be bonded to the substrate.

5. The system of claim 1, further comprising:
at least one conductive wire disposed on the substrate and connected to a primary substrate pad and a corresponding repair substrate pad.

6. The system of claim 5, wherein the at least one conductive wire comprises an original conductive wire that is electrically connected to the primary substrate pad, and is extended and directly connected to the corresponding repair substrate pad.

7. The system of claim 5, wherein the at least one conductive wire comprises an extra conductive wire that is indirectly connected to both the primary substrate pad and the corresponding repair substrate pad.

8. The system of claim 5, wherein the at least one conductive wire comprises an original conductive wire that is electrically connected to the primary substrate pad and is extended with an original direction changed and indirectly connected to the corresponding repair substrate pad.

9. The system of claim 5, wherein the primary substrate pad, the corresponding repair substrate pad and the at least one conductive wire are disposed on a same layer above the substrate.

10. The system of claim 5, wherein the primary substrate pad and the corresponding repair substrate pad are disposed above the at least one conductive wire.

11. The system of claim 5, wherein the corresponding repair substrate pad is disposed above the primary substrate pad and the at least one conductive wire.

12. The system of claim 5, wherein the primary substrate pad is disposed above the corresponding repair substrate pad and the at least one conductive wire.

13. A flip chip assembly, comprising:
a chip that is flipped;
a reflow area in a front portion of the chip;
at least one metal layer disposed in the front portion of the chip and bypassing the reflow area;
a plurality of chip pads located in the front portion of the chip and electrically connected to a metal layer;
a substrate;
a plurality of substrate pads disposed on the substrate; and
a plurality of solder bumps, via which the plurality of substrate pads are electrically connected to the plurality of chip pads;
wherein laser heating passes through the chip and the reflow area to melt the plurality of solder bumps.

14. The assembly of claim 13, wherein the at least one metal layer in the chip bypasses the reflow area in the front portion of the chip accommodating a corresponding chip pad and the reflow area is vertically aligned with the laser heating and the corresponding chip pad.

15. The assembly of claim 13, wherein the reflow area in the front portion of the chip is vertically aligned with the laser heating and is outside an area corresponding to the at least one metal layer.

16. The assembly of claim 15, wherein the reflow area does not accommodate a corresponding chip pad that is located in the aera corresponding to the at least one metal layer.

17. The assembly of claim 15, wherein the reflow area is in a periphery area of the area corresponding to the at least one metal layer.

18. The assembly of claim 15, wherein a solder bump is elongated in shape to connect to a surface of the reflow area at one end and connect to a corresponding chip pad at an opposite end.

19. The assembly of claim 13, wherein the plurality of solder bumps, the plurality of chip pads and the plurality of substrate pads result in eutectic mixture after being subjected to the laser heating.

20. The assembly of claim 13, wherein the laser heating is projected on a back of the chip.
